(19) United States
(12) Patent Application Publication
(10) Pub. No.: US 2017/0371741 A1
(43) Pub. Date: Dec. 28, 2017

(54) TECHNOLOGIES FOR PROVIDING FILE-BASED RESILIENCY

(71) Applicant: Intel Corporation, Santa Clara, CA (US)

(72) Inventor: Vinodh Gopal, Westborough, MA (US)

(21) Appl. No.: 15/193,337

(22) Filed: Jun. 27, 2016

(51) Int. Cl. G06F 11/10; H03M 13/15; H03M 13/09

(52) U.S. Cl. CPC G06F 11/1004; H03M 13/09; H03M 13/154

(57) ABSTRACT

Technologies for providing file-based data resiliency include an apparatus having a memory to store file data and a processor to manage encode or decode operations on the file data. The processor is to determine an increase in file size to be allocated for a reserved portion of a file to be stored in the memory, generate an erasure code based on content of the file and the determined increase in file size, wherein the erasure code is to facilitate decorruption of the file, and write the erasure code to the reserved portion of the file.

### BACKGROUND

As technologies increasingly move towards cloud-based storage, users will increasingly opt to encrypt their data to enhance the privacy of their data. As the amount of data stored in the cloud grows, so does the problem of bit-errors in storage. Typically, service providers of storage will store user files in a “tiered” storage system, based on access patterns (e.g., hot/cold) and/or price points for services. These different tiers may use various forms of data replication and mirroring, and/or coding schemes such as bit-level error correction codes (ECC), storage-block-level redundant arrays of inexpensive disks (RAID) or erasure codes (EC) to enhance the reliability of the data. However, the typical user may not fully know and understand what level of reliability is associated with a file through its lifetime. Although unlikely, it is possible that there may be some data corruption of bits in the user data, including some amount that is detected but uncorrected by the storage service provider and some amount that is silent or undetected. If such corruption occurs to an encrypted file, the corruption is greatly amplified during the decryption process. Conventional techniques for protecting against corruption of files include redundant arrays of inexpensive disks (RAID) systems in which data recovery operations are applied at the disk level and recovery of the data requires knowledge of which disk failed. Further, in such systems, the level of data resiliency is constant across all data in the system, rather than being adaptable based on the type or priority of different sets of data.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified block diagram of at least one embodiment of a system for providing file-based data resiliency that includes a compute device in communication with a server through a network;

FIG. 2 is a simplified block diagram of at least one embodiment of a data storage device included in the compute device of FIG. 1;

FIG. 3 is a simplified block diagram at least one embodiment of an environment that may be established by the compute device of FIG. 1;

FIGS. 4-6 are a simplified flow diagram of at least one embodiment of a method for encoding a file that may be executed by the compute device of FIG. 1; and

FIG. 7 is a simplified flow diagram of at least one embodiment of a method for decoding a file that may be executed by the compute device of FIG. 1.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

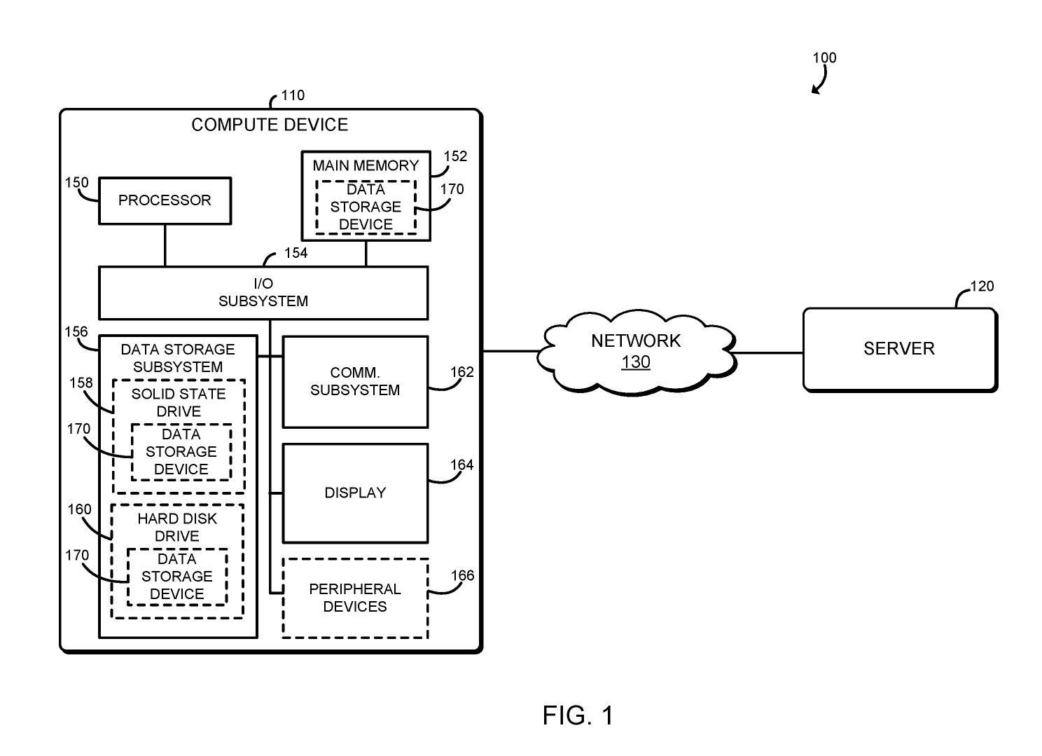

As shown in FIG. 1, an illustrative system for providing file-based data resiliency includes a compute device 110 communicatively coupled to a server 120 through a network 130. Although illustrated as a single server 120 for simplicity, it should be understood that the server 120 may be embodied as a plurality of servers of a cloud system for storing user data on behalf of a user (not shown) of the compute device 110. As discussed in more detail herein, in operation, the compute device 110 is configured to allocate a reserved portion for each file that is to be stored in the cloud (e.g., in memory or storage of server 120), generate erasure codes based on the content of each file, and store the erasure codes in the respective reserved portions of the files prior to providing the files to the server 120 for storage. The erasure codes provide enhanced resiliency to the data of the files and enable data corruption to be more easily detected and corrected. Further, in the illustrative embodiment, the compute device 110 is configured to receive one or more of the files from the server 120, detect, using checksums, whether one or more sections of the files have been corrupted while stored on the server 120, and correct the corrupted portions using the erasure codes stored in the reserved portions of the files. In the illustrative embodiment, the encoding and decoding of the files is performed on the client side (i.e., by the compute device 110) and is transparent to the server 120, which may apply its own encoding and decoding processes on the files, including data encryption and/or decryption. By providing the enhanced resiliency to data at the file level, rather than at the disk level, a user is given flexibility over the amount of data resiliency that will be provided for a given set of data. Accordingly, a user can more precisely balance desired data resiliency levels against storage capacity usage.

In the illustrative embodiment, the compute device 110 may be embodied as any type of computing device capable of performing the functions described herein, including encoding files with erasure codes prior to providing them to the server 120 for storage, and decoding the files after receiving the files from the server to detect and correct corruption of the data. For example, the compute device 110 may be embodied as a desktop computer, a notebook, a laptop computer, a netbook, an Ultrabook™, a smart phone, a tablet computer, a cellular phone, a smart device, a personal digital assistant, a mobile Internet device, a server, a data storage device, and/or any other computing/communication device. As shown in FIG. 1, the illustrative compute device 110 includes a processor 150, a main memory 152, an input/output (“I/O”) subsystem 154, a data storage subsystem 156, and a communication subsystem 162. Of course, the compute device 110 may include other or additional components, such as those commonly found in a typical computing device (e.g., various input/output devices and/or other components), in other embodiments. Additionally, in some embodiments, one or more of the illustrative components may be incorporated in, or otherwise form a portion of, another component. For example, the memory 152, or portions thereof, may be incorporated in the processor 150 in some embodiments.

The processor 150 may be embodied as any type of processor capable of performing the functions described herein. For example, the processor 150 may be embodied as a single or multi-core processor(s), digital signal processor, microcontroller, or other processor or processing/controlling circuit. Similarly, the memory 152 may be embodied as any type of volatile or non-volatile memory or data storage capable of performing the functions described herein. In operation, the memory 152 may store various data and software used during operation of the compute device 110 such as operating systems, applications, programs, libraries, and drivers. The memory 152 is communicatively coupled to the processor 150 via the I/O subsystem 154, which may be embodied as circuitry and/or components to facilitate input/output operations with the processor 150, the memory 152, and other components of the compute device 110. For example, the I/O subsystem 154 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. In some embodiments, the I/O subsystem 154 may form a portion of a system-on-a-chip (SoC) and be incorporated, along with the processor 150, the memory 152, and other components of the compute device 110, on a single integrated circuit chip.

The data storage subsystem 156, which may be embodied as any type of device or devices configured for short-term or long-term storage of data such as, for example, one or more solid state drives (SSDs) 158, one or more hard disk drives (HDDs) 160, memory devices and circuits, memory cards, or other data storage devices. The data storage subsystem 156 may store data and software used during operation of the compute device 110 such as user files to be provided to and receive from a cloud storage system (e.g., the server 120), rules for encoding and decoding the files, operating systems, applications, programs, libraries, and drivers, as described in more detail herein.

The illustrative compute device 110 additionally includes the communication subsystem 162. The communication subsystem 162 may be embodied as one or more devices and/or circuitry capable of enabling communications with one or more other compute devices, such as the server 120, over a network (e.g., the network 130). The communication subsystem 162 may be configured to use any suitable communication protocol to communicate with other devices including, for example, wired communication protocols, wireless data communication protocols, and/or cellular communication protocols.

The compute device 110 may additionally include a display 164, which may be embodied as any type of display device on which information may be displayed to a user of the compute device 110. The display 164 may be embodied as, or otherwise use, any suitable display technology including, for example, a liquid crystal display (LCD), a light emitting diode (LED) display, a cathode ray tube (CRT) display, a plasma display, and/or other display usable in a compute device. The display 164 may include a touchscreen sensor that uses any suitable touchscreen input technology to detect the user's tactile selection of information displayed on the display including, but not limited to, resistive touchscreen sensors, capacitive touchscreen sensors, surface acoustic wave (SAW) touchscreen sensors, infrared touchscreen sensors, optical imaging touchscreen sensors, acoustic touchscreen sensors, and/or other type of touchscreen sensors.

In some embodiments, the compute device 110 may further include one or more peripheral devices 166. Such peripheral devices 166 may include any type of peripheral device commonly found in a compute device such as speakers, a mouse, a keyboard, and/or other input/output devices, interface devices, and/or other peripheral devices.

As shown in FIG. 1, a data storage device 170 may be incorporated in, or form a portion of, one or more other components of the compute device 110. For example, the data storage device 170 may be embodied as, or otherwise be included in, the main memory 152. Additionally or alternatively, the data storage device 170 may be embodied as, or otherwise included in, the solid state drive 158 of the compute device 110. Further, in some embodiments, the data storage device 170 may be embodied as, or otherwise included in, the hard disk drive 160 of the compute device 110. Of course, in other embodiments, the data storage device 170 may be included in or form a portion of other components of the compute device 110. As described in more detail herein, in the illustrative embodiment, the data storage device 170 is configured to perform one or more processes to encode files with erasure codes before they are provided to the server 120 for storage, and decoding the files after the files are received from the server, to detect and correct corruption of the data, as described in more detail herein.

The server 120 may include components commonly found in a compute device, such as a processor, memory, I/O subsystem, data storage, communication subsystem, etc. Those components may be substantially similar to the corresponding components of the compute device 110. As such, further descriptions of the like components are not repeated herein with the understanding that the description of the corresponding components provided above in regard to the compute device 110 applies equally to the corresponding components of the server 120.

As described above, the compute device 110 and the server 120 of the system 100 are illustratively in communication via the network 130, which may be embodied as any number of various wired or wireless networks. For example, the network 130 may be embodied as, or otherwise include, a publicly-accessible, global network such as the Internet, a wired or wireless wide area network (WAN), a wired or wireless local area network (LAN), and/or a cellular network. As such, the network 130 may include any number of additional devices, such as additional computers, routers, and switches, to facilitate communications among the devices of the system 100.

Reference to memory devices can apply to different memory types, and in particular, any memory that has a bank group architecture. Memory devices generally refer to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR4 (DDR version 4, initial specification published in September 2012 by JEDEC), DDR4E (in development by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (currently in discussion by JEDEC), HBM2 (HBM version 2), currently in discussion by JEDEC), and/or others, and technologies based on derivatives or extensions of such specifications.

In addition to, or alternatively to, volatile memory, in one embodiment, reference to memory devices can refer to a nonvolatile memory device whose state is determinate even if power is interrupted to the device.

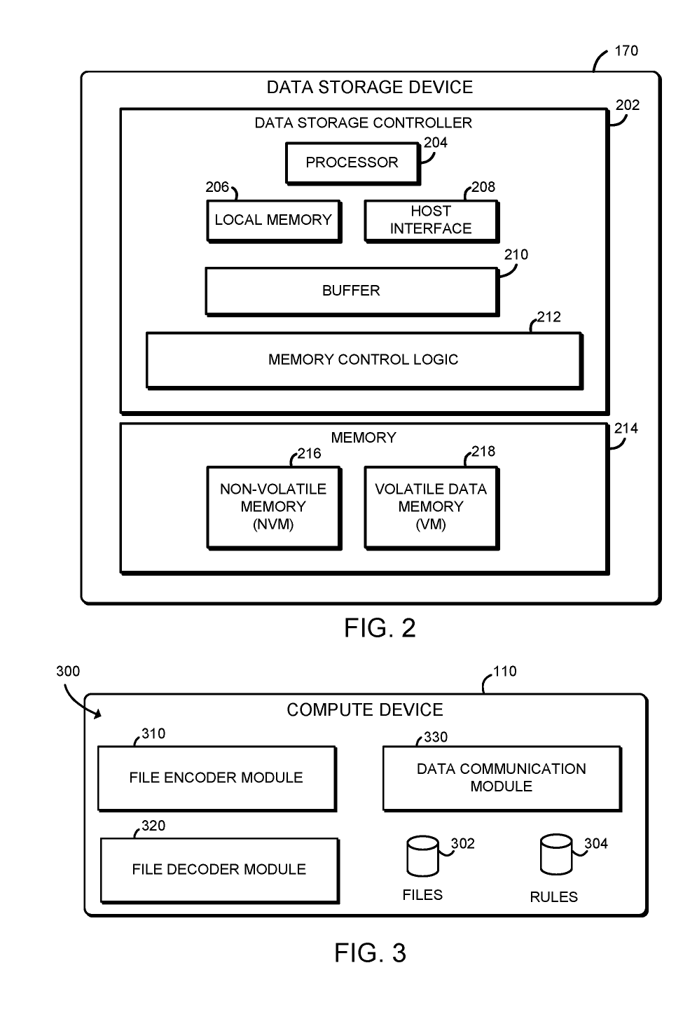

Referring now to FIG. 2, the data storage device 170 includes a data storage controller 202 and a memory 214, which illustratively includes non-volatile memory 216 and volatile memory 218. The data storage controller 202 may be embodied as any type of control device, circuitry, or collection of hardware devices capable of performing the functions described herein. In the illustrative embodiment, the data storage controller 202 includes a processor or processing circuitry 204, local memory 206, a host interface 208, a buffer 210, and memory control logic (also referred to herein as a “memory controller”) 212. The memory controller 212 can be in the same die or integrated circuit as the processor 204 or the memory 206, 214 or in a separate die or integrated circuit than those of the processor 204 and the memory 206, 214. In some cases, the processor 204, the memory controller 212, and the memory 206, 214 can be implemented in a single die or integrated circuit. Of course, the data storage controller 202 may include additional devices, circuits, and/or components commonly found in a drive controller of a solid state drive in other embodiments.

The processor 204 may be embodied as any type of processor capable of performing the functions described herein. For example, the processor 204 may be embodied as a single or multi-core processor(s), digital signal processor, microcontroller, or other processor or processing/controlling circuit. Similarly, the local memory 206 may be embodied as any type of volatile and/or non-volatile memory or data storage capable of performing the functions described herein. In the illustrative embodiment, the local memory 206 stores firmware and/or other instructions executable by the processor 204 to perform the described functions of the data storage controller 202. In some embodiments, the processor 204 and the local memory 206 may form a portion of a System-on-a-Chip (SoC) and be incorporated, along with other components of the data storage controller 202, onto a single integrated circuit chip.

The host interface 208 may also be embodied as any type of hardware processor, processing circuitry, input/output circuitry, and/or collection of components capable of facilitating communication of the data storage device 170 with a host device or service (e.g., a host application). That is, the host interface 208 embodies or establishes an interface for accessing data stored on the data storage device 170 (e.g., stored in the memory 214). To do so, the host interface 208 may be configured to utilize any suitable communication protocol and/or technology to facilitate communications with the data storage device 170 depending on the type of data storage device. For example, the host interface 208 may be configured to communicate with a host device or service using Serial Advanced Technology Attachment (SATA), Peripheral Component Interconnect express (PCIe), Serial Attached SCSI (SAS), Universal Serial Bus (USB), and/or other communication protocol and/or technology in some embodiments.

The buffer 210 of the data storage controller 202 is embodied as volatile memory used by data storage controller 202 to temporarily store data that is being read from or written to the memory 214. The particular size of the buffer 210 may be dependent on the total storage size of the memory 214. The memory control logic 212 is illustratively embodied as hardware circuitry and/or one or more devices configured to control the read/write access to data at particular storage locations of the memory 214.

The non-volatile memory 216 may be embodied as any type of data storage capable of storing data in a persistent manner (even if power is interrupted to non-volatile memory 216). For example, in the illustrative embodiment, the non-volatile memory 216 is embodied as one or more non-volatile memory devices. The non-volatile memory devices of the non-volatile memory 216 are illustratively embodied as three dimensional NAND (“3D NAND”) non-volatile memory devices. However, in other embodiments, the non-volatile memory 216 may be embodied as any combination of memory devices that use chalcogenide phase change material (e.g., chalcogenide glass), three-dimensional (3D) crosspoint memory, or other types of byte-addressable, write-in-place non-volatile memory, ferroelectric transistor random-access memory (FeTRAM), nanowire-based non-volatile memory, phase change memory (PCM), memory that incorporates memristor technology, Magnetoresistive random-access memory (MRAM) or Spin Transfer Torque (STT)-MRAM.

The volatile memory 218 may be embodied as any type of data storage capable of storing data while power is supplied volatile memory 218. For example, in the illustrative embodiment, the volatile memory 218 is embodied as one or more volatile memory devices, and is periodically referred to hereinafter as volatile memory 218 with the understanding that the volatile memory 218 may be embodied as other types of non-persistent data storage in other embodiments. The volatile memory devices of the volatile memory 218 are illustratively embodied as dynamic random-access memory (DRAM) devices, but may be embodied as other types of volatile memory devices and/or memory technologies capable of storing data while power is supplied to volatile memory 218.

Referring now to FIG. 3, in use, the compute device 110 of the system 100 may establish an environment 300. The illustrative environment 300 includes a file encoder module 310, a file decoder module 320, and a data communication module 330. Each of the modules and other components of the environment 300 may be embodied as firmware, software, hardware, or a combination thereof. For example the various modules, logic, and other components of the environment 300 may form a portion of, or otherwise be established by, the compute device 110 or other hardware components of the compute device 110, such as the data storage device 170. As such, in some embodiments, any one or more of the modules of the environment 300 may be embodied as a circuit or collection of electrical devices (e.g., a file encoder circuit 310, a file decoder circuit 320, a data communication circuit 330, etc.). In the illustrative embodiment, the environment 300 includes files 302, such as files that include user data (e.g., documents, images, audio, etc.) and rules 304, which may include predefined rules for determining an amount of additional storage to allocate to each file 302 as a function of a user selection of an amount of data resiliency to apply to the file, as a function of the file types, or other criteria, and/or algorithms for encoding the files 302 to enhance their resiliency and decoding the files to detect and correct any corruption in the files 302. The files 302 and the rules 304 may be accessed by the various modules and/or sub-modules of the compute device 110.

In the illustrative embodiment, the file encoder module 310, which may be embodied as hardware, firmware, software, virtualized hardware, emulated architecture, and/or a combination thereof as discussed above, is configured to determine an increase in file size to be allocated for a reserved portion of a file 302, generate one or more erasure codes based on content of the file 302 and the determined increase in file size, and write the erasure codes to the reserved portion of the file 302. In the illustrative embodiment, the file encoder module 310 is configured to identify multiple blocks of a predefined size, such as 64 bytes, and generate an erasure code for each of the blocks of the file 302. In doing so, the file encoder module 310 may be configured to generate a parity syndrome and a Galois field syndrome for each block of the file. The file encoder module 310 may further be configured to partition the file into superblocks and sub-blocks, such as 8 kilobyte superblocks that contain multiple sub-blocks that are 64 bytes in size. Additionally or alternatively, the file encoder module 310 may be configured to determine an erasure code for each sub-block, determine a cyclic redundancy check (CRC) checksum for each sub-block, and determine a CRC checksum for each erasure code, and store this data in the file before the file is provided to the server 120 for storage. In the illustrative embodiment, the file encoder module 310 is configured to store the erasure codes and checksums in the reserved portion of the file 302. Further, as described in more detail herein, in some embodiments, the reserved portion of the file is interleaved with the original content of the file (i.e., the data of the file before the reserved portion was allocated).

In the illustrative embodiment, the file decoder module 320, which may be embodied as hardware, firmware, software, virtualized hardware, emulated architecture, and/or a combination thereof as discussed above, is configured to read a file 302, determine whether the file includes one or more corrupted sections, and recover the one or more corrupted sections based on the erasure codes stored in the reserved portion of the file 302. Further, in the illustrative embodiment, the file decoder module 320 is configured to determine whether the file 302 includes a corrupted portion by determining a checksum associated with the portion to be examined, compare the determined checksum to a corresponding checksum stored in the reserved portion of the file, and determine whether the determined checksum matches the checksum from the reserved portion of the file to determine whether that section of the file is corrupted. In the illustrative embodiment, the file decoder module 320 is configured to determine that the section of the file 302 is corrupted if the two checksums do not match (e.g., are not equal) and otherwise determine that the section is not corrupted. If the file decoder module 320 determines that the section is corrupted, the illustrative file decoder module 320 is further configured to recover the corrupted section based on the erasure code stored in the reserved portion of the file 302 in association with the corrupted section. In doing so, the file decoder module 320 may perform a matrix inversion process based on the erasure code, to recover the original data. In the illustrative embodiment, the file decoder module 320 is configured to perform the data recovery process described above for each section of the file (i.e., each block or sub-block) that the file decoder module 320 determines to be corrupted.

In the illustrative embodiment, the data communication module 330, which may be embodied as hardware, firmware, software, virtualized hardware, emulated architecture, and/or a combination thereof as discussed above, is configured to transmit data to one or more remote compute devices and receive data from one or more remote compute devices. In the illustrative embodiment, the data communication module 330 is configured to transmit one or more files 302 to the server 120 through the network 130 for storage thereon, such as in response to a user request to store the file on the cloud, and to request and receive one or more of the files 302 from the server 120 at a later time, such as in response to a user request to view or edit the file 302. As described above, in the illustrative embodiment, the compute device 110 is configured to encode the files 302 with erasure codes prior to transmission of the files to the server 120 and to receive the files 302 at a later time with the erasure codes stored therein, for use in correcting any data corruption that may have occurred while the files were stored.

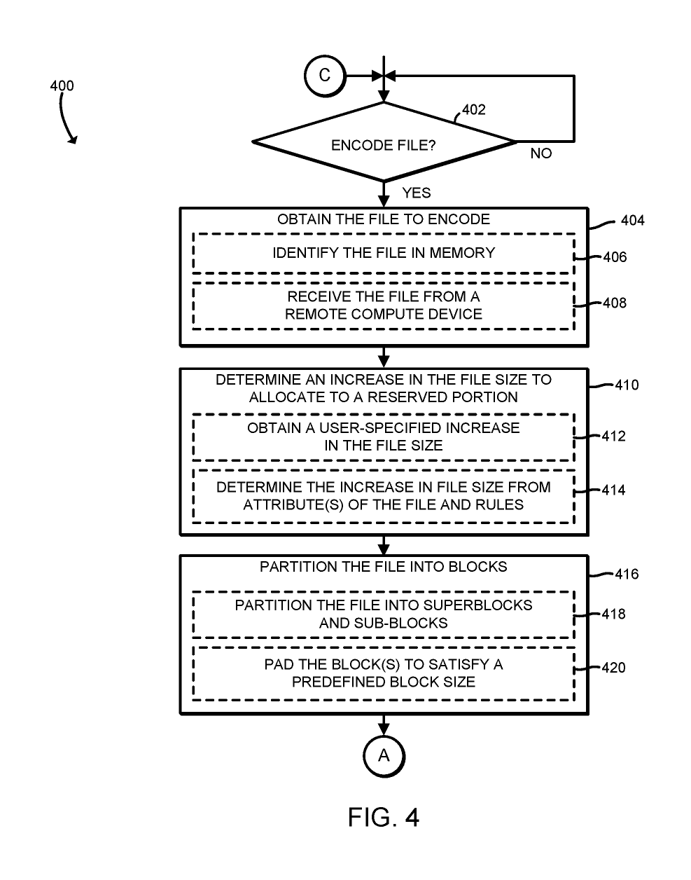

Referring now to FIG. 4, in use, the compute device 110 may execute a method 400 for encoding a file 302 to include erasure codes to assist in correcting data corruption that may later occur in the file 302. The method 400 begins with block 402 in which the compute device 110 determines whether to encode the file 302. For example, the compute device 110 may receive a request from a user to store the file 302 in cloud storage (e.g., the server 120) and determine to encode the file 302 prior to transmitting the file 302 to the server 120 for storage. Additionally or alternatively, the compute device 110 may determine to encode the file 302 for enhanced data resiliency regardless of whether the file 302 is to be stored on the server 120. For example, the compute device 110 may determine to encode the file in response to any save request from the user or in response to a scheduled save of the file 302 (e.g., a periodic log file, a file generated in response to a predefined system event, etc.). Regardless, if the compute device 110 determines to encode the file 302, the method 400 advances to block 404 in which the compute device 110 obtains the file 302 to encode. In doing so, the compute device 110 may identify the file 302 as an existing file stored in memory (e.g., in the data storage subsystem 156 or in main memory 152), as indicated in block 406. As an example, the file 302 may be a document that a user is editing in a word processor. As such, the file 302 may be located in main memory 152. In other embodiments, the compute device 110 may receive (e.g., download) the file from a remote compute device (not shown), using the communication subsystem 162, as indicated in block 408. In other embodiments, the compute device 110 may obtain the file 302 from another source.

In block 410, the compute device 110 determines an increase in the file size to allocate to a reserved portion of the file 302. The reserved portion of the file 302 is to be used to store data, such as erasure codes and checksums for use in detecting and correcting any subsequent corruption of the content of the file. In general, the amount of data corruption detection and correction available for a given file is a function of the size of the reserved portion of the file. Accordingly, the compute device 110 may allocate larger reserved portions to higher priority files and smaller reserved portions to lower priority files. To determine the increase in file size to be allocated to the reserved portion, the compute device 110 may obtain a user-specified increase in the file size, such as through a graphical user interface (not shown), as indicated in block 412. Additionally or alternatively, the compute device 110 may determine the increase in file size from attributes of the file 302 and the rules 304, as indicated in block 414. As an example, in the illustrative embodiment, the rules 304 may specify that spreadsheet files are to receive relatively larger reserved portions than other types of files, such as audio files or image files. Additionally or alternatively, in the illustrative embodiment, the rules 304 may specify that encrypted and/or compressed files, such as files having a header, file name extension, or metadata identifying the file as encrypted and/or compressed are to receive relatively larger reserved portions. This is advantageous because a corrupted set of data in an encrypted or compressed file tends to increase in size and affect other portions of the file during the decryption or decompression process. By contrast, the rules 304 may specify that media files (e.g., video, image, and audio files) are to receive relatively smaller reserved portions, as these file types are less affected by corruption and tend to already be relatively large in size. For example, many media files are stored in a lossy format, meaning a portion of the original data is lost when the file is stored in a lossy media format such as JPEG or MPEG-2 Audio Layer III (MP3). Such losses in media files tend to go unnoticed by humans By allocating relatively smaller reserved portions to media files, the compute device 110 may lessen the additional amount of storage that these file types consume while still providing data resiliency. Other file types, such documents may receive a default-sized reserved portion, unless otherwise specified by the user. Accordingly, the compute device 110 may determine the file type based on attributes of the file, such as a file name extension, a header portion of the file, or other metadata, and look up the amount by which to increase the file size from the rules 304, based on the file type. In other embodiments, the attributes of the file 302 that may affect the size of the reserved portion may include a date and/or time when the file was generated, a location in a file system where the file is stored, an author or owner of the file, or any other attributes that characterize the file.

In block 416, the compute device 110 partitions the file 302 into blocks. In doing so, in the illustrative embodiment, the compute device 110 partitions the file 302 into superblocks and sub-blocks contained within the superblocks, as indicated in block 418. Further, in the illustrative embodiment, the superblocks are four or eight kilobytes in size and each sub-block is 64 bytes in size. These sizes are advantageous as they enable efficient and effective correction of data corruption without unduly increasing the file size. It should be understood however, that for a file in which the reserved portion is a larger percentage of the file, the sub-blocks may be smaller in size to provide even greater resiliency, and vice versa. Further, the sizes of the blocks may be varied depending on the total number of blocks desired and the size of the file. As indicated in block 420, in the illustrative embodiment, the compute device 110 pads one or more of the blocks to satisfy a predefined block size. In other words, the compute device 110 may add zeros or another value to a block to increase the size of the block to meet a threshold size (e.g., 64 bytes).

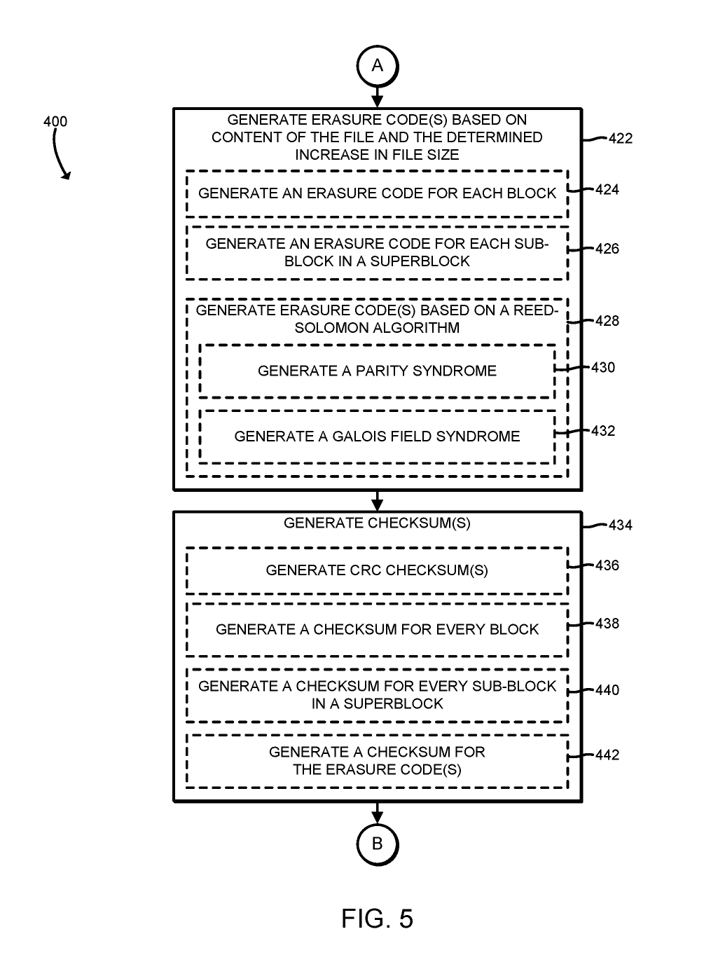

After partitioning the file 302 into blocks, the method 400 advances to block 422 of FIG. 5 in which the compute device 110 generates one or more erasure codes based on the content of the file 302 and the determined increase in the file size. In doing so, in the illustrative embodiment, the compute device 110 generates an erasure code for each block, as indicated in block 424. As indicated in block 426, in the illustrative embodiment, the compute device 110 generates an erasure code for each sub-block contained within a superblock. The type of erasure code may vary from embodiment to embodiment. However, in the illustrative embodiment, the compute device 110 generates the one or more erasure codes based on a Reed-Solomon algorithm, as indicated in 428. In doing so, the compute device 110 generates a parity syndrome as indicated in block 430, and generates a Galois field syndrome, as indicated in block 432. In generating the Galois field syndrome, the compute device 110 determines a size for the Galois fields. In the illustrative embodiments, the compute device 110 uses either 16-bit Galois fields or 8-bit Galois fields. In other embodiments, the compute device 110 may use other sized Galois fields, such as a size based on user preferences. In general, the number of superblocks that the file can be partitioned into is dependent on the number of bits in the Galois field. Further, in the illustrative embodiment, in determining the size for the Galois fields, the compute device 110 determines a size that will provide more than twenty redundancies. Additionally, the compute device 110 determines coefficients to generate a Galois field Vandermonde matrix to be used to compute the syndromes. The matrix can be inverted in the Galois field to enable the data to be reconstructed, as described herein with reference to the decode method 700.

Still referring to FIG. 5, as indicated in block 434, the compute device 110 additionally generates one or more checksums to be used in detecting corruption in the file 302. In the illustrative embodiment, the compute device 110 generates the checksums as CRC checksums, as indicated in block 436. Additionally, in the illustrative embodiment, the compute device 110 generates a checksum for each block in the file 302, as indicated in block 438. In the illustrative embodiment, the compute device 110 generates the checksum for every sub-block (e.g., every 64 byte sub-block) within a corresponding superblock (e.g., every four or eight kilobyte superblock). In the illustrative embodiment, for every 64 byte sub-block, the compute device 110 generates a 4 byte CRC checksum and appends it to the sub-block, causing the sub-block to be 68 bytes in size. Additionally, as an added measure of data resiliency, the compute device 110 may generate a checksum for each of the erasure codes generated above, for use in detecting, at a later time (e.g., during a decoding process), whether the erasure codes themselves have been corrupted, as indicated in block 442.

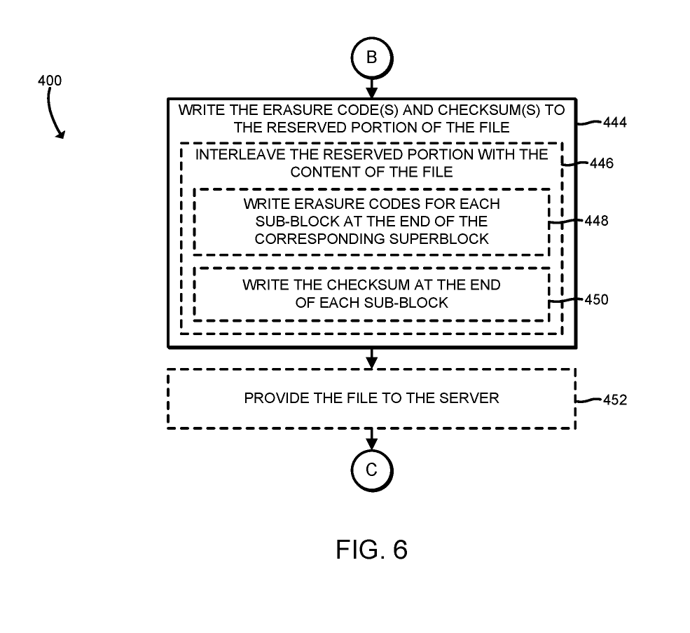

Referring now to FIG. 6, after generating the erasure codes and the checksums, the compute device writes the erasure codes and checksums to the reserved portion of the file 302, as indicated in block 444. As indicated in block 446, in the illustrative embodiment, the compute device 110 interleaves the reserved portion of the file 302 with the original content of the file 302. In doing so, as indicated in block 448, the compute device 110 may write the erasure codes for each sub-block at the end of the corresponding superblock that contains the sub-block and, as indicated in block 450, the compute device 110 may write the checksum for a given sub-block at the end of the sub-block. As indicated in block 452, after writing the erasure codes and checksums to the reserved portion of the file, the compute device 110 may provide the file 302 to a remote compute device (e.g., the server 120) for storage.

As an example of the above process, in the illustrative embodiment, the compute device 110 partitions a file into 8 kilobyte superblocks, wherein each 8 kilobyte superblock is composed of 128 sub-blocks that are 64 bytes each. The superblock may be represented as SB[128]. Each element (i.e., sub-block) SB[i] is 64 bytes. If the user indicates ¼^{th} expansion in file size for the erasure codes, the compute device 110 generates 32 extra sub-blocks (i.e., 128 divided by 4), that are denoted EC[0], . . . EC[31], wherein each EC[i] is 64 bytes. Using Reed-Solomon coding, the compute device 110 generates an 8-bit Galois field using, as an example, polynomial 0x1D. For each byte of the sub-blocks, the illustrative compute device 110 calculates an EC (i.e., erasure code) byte as:

EC[0]=SB[0] ⊕ SB[1] . . . ⊕ SB[127] (Equation 1)

EC[i]=SB[0] ⊕ 2⁽ⁱ⁾.SB[1] . . . ⊕ 128⁽ⁱ⁾.SB[127] (Equation 2)

In Equation 2, i represents the index of the erasure code syndrome block, in the range of 0-31. The illustrative compute device 110 also calculates a 32-bit CRC for each sub-block and EC block. The final transformed file is composed of the combined blocks, and, in the illustrative embodiment, has the following format: B[0]∥CRC(B[0]) . . . B[127]∥CRC(B[127]), EC[0]∥CRC(EC[0]) . . . EC[31]∥CRC(EC[31]).

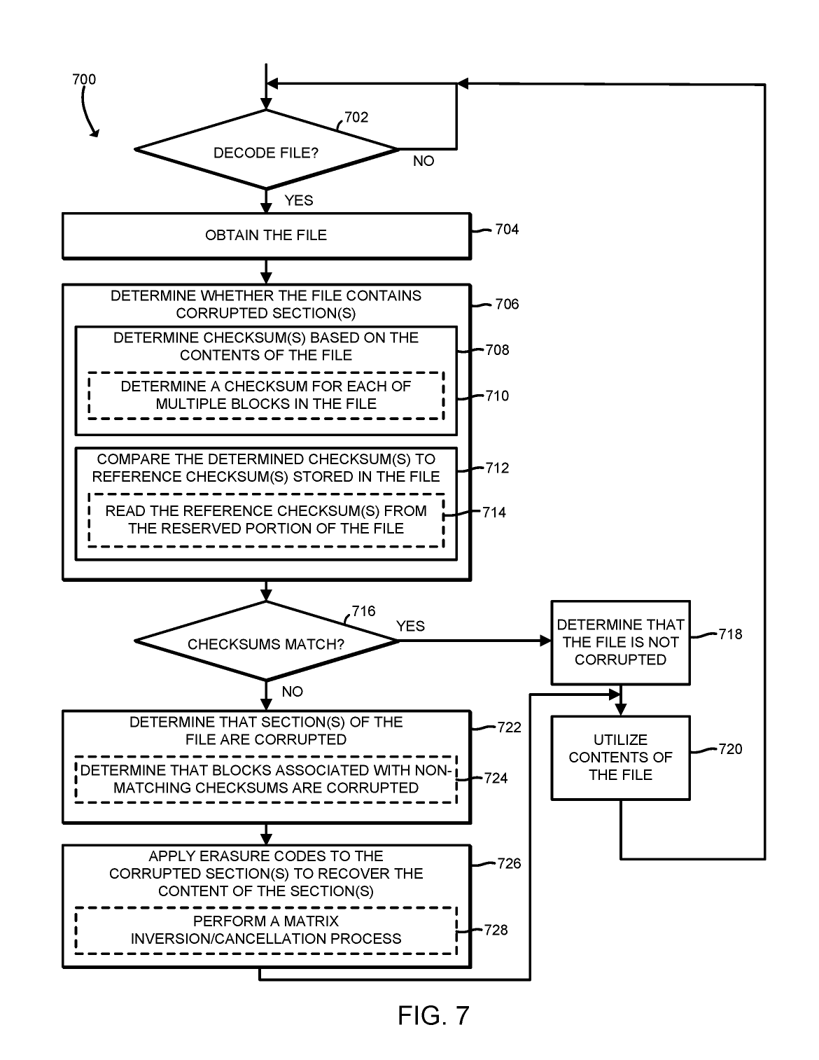

Referring now to FIG. 7, the compute device 110 may execute a method 700 for decoding a file 302 to potentially identify and correct data corruption in the file 302. The method 700 begins with block 702 in which the compute device 110 determines whether to decode the file 302. In the illustrative embodiment, the compute device 110 determines to decode a file in response to user request provided through a graphical user interface (not shown) to open a file stored locally or on the cloud (e.g., stored by the server 120). In other embodiments, the compute device 110 determines whether to decode a file based on other factors. Regardless, if the compute device 110 determines to decode a file, the compute device 110 obtains the file to be decoded, as indicated in block 704. In doing so, the compute device 110 may read the file from local storage (e.g., the data storage subsystem 156) or receive the file from a remote compute device (e.g., the server 120).

In block 706, the compute device 110 determines whether the file 302 contains one or more corrupted sections. In doing so, the compute device 110 may determine checksums based on the content of the file 302, as indicated in block 708. In the illustrative embodiment, the compute device 110 determines a checksum for each of multiple blocks in the file 302 (e.g., each sub-block), as indicated in block 710. The checksum may be a CRC checksum, or other type of value or set of values calculated based on the content of a block or sub-block. Further, as indicated in block 712, the illustrative compute device 110 compares the determined checksums to corresponding reference checksums stored in the file 302. In the illustrative embodiment, the compute device 110 reads the reference checksums from the reserved portion of the file 302, as indicated in block 714. As described above, the checksums may be stored at the end of each block or sub-block of data, such that the reserved portion of the file is interleaved with the original data of the file 302.

In block 716, the compute device 110 determines whether the determined checksums match the reference checksums stored in the file 302. If so, the compute device 110 determines that the file 302 is not corrupted, as indicated in block 718 and the compute device 110 may present the content of the file 302 to the user or otherwise use the content of the file 302, as indicated in block 720. Referring back to block 716, if the compute device 110 determines that one or more of the checksums do not match (i.e., are not equal), the compute device 110 determines that the sections of the file are corrupted, as indicated in block 722. In doing so, the compute device 110 may determine that the blocks associated with non-matching checksums (i.e., the determined checksum calculated from the present content of the block are not equal to the corresponding reference checksums stored in the reserved portion of the file 302 for those blocks) are corrupted, as indicated in block 724. In block 726, in the illustrative embodiment, the compute device 110 applies the erasure codes stored in the reserved portion of the file 302 to the corrupted sections (e.g., corrupted blocks) to recover the content of those sections. In doing so, as indicated in block 728, the compute device 110 may perform a matrix inversion or cancellation process using the erasure codes to correct the corruption in those sections. After the compute device 110 applies the erasure codes to recover the content of the file 302, the method 700 advances to block 720, in which the compute device 110 uses the content of the file 302, such as by presenting the content of the file 302 to the user.

### EXAMPLES

Illustrative examples of the technologies disclosed herein are provided below. An embodiment of the technologies may include any one or more, and any combination of, the examples described below.

Example 1 includes a memory to store file data; and a processor to manage encode or decode operations on the file data, wherein the processor is to determine an increase in file size of a file to be stored in memory, wherein the increase in the file size of the file is to define a reserved portion of the file; generate an erasure code based on content of the file and the determined increase in file size, wherein the erasure code is to facilitate decorruption of the file; and write the erasure code to the reserved portion of the file.

Example 2 includes the subject matter of Example 1, and wherein the processor is further to generate a cyclic redundancy check (CRC) checksum based on the content of the file; and store the CRC checksum in the reserved portion of the file.

Example 3 includes the subject matter of Examples 1 and 2, and wherein the reserved portion of the file is interleaved with the content of the file.

Example 4 includes the subject matter of Examples 1-3, and wherein the apparatus further includes network communication circuitry to transmit the file to a remote server compute device after storage of the erasure code in the reserved portion of the file.

Example 5 includes the subject matter of Examples 1-4, and wherein the processor is further to read the file from the memory; determine whether the file includes a corrupted section; and recover, in response to a determination that the file includes a corrupted section, the corrupted section based on the erasure code in the reserved portion of the file.

Example 6 includes the subject matter of Examples 1-5, and wherein to recover the corrupted section comprises to perform a matrix inversion process based on the erasure code.

Example 7 includes the subject matter of Examples 1-6, and wherein to determine whether the file includes a corrupted portion comprises to generate a checksum associated with the corrupted section of the file; compare the generated checksum to a reference checksum stored in the reserved portion of the file; determine whether the generated checksum matches the reference checksum; determine, in response to a determination that the generated checksum matches the reference checksum, that the section is not corrupted; and determine, in response to a determination that the generated checksum does not match the reference checksum, that the section is corrupted.

Example 8 includes the subject matter of Examples 1-7, and wherein the apparatus further includes network communication circuitry to receive the file from a remote server compute device before the determination of whether the file includes a corrupted portion.

Example 9 includes the subject matter of Examples 1-8, and wherein the processor is further to determine the increase in file size based on an attribute associated with the file.

Example 10 includes the subject matter of Examples 1-9, and wherein to generate an erasure code includes to generate the erasure code based on a Reed-Solomon algorithm.

Example 11 includes the subject matter of Examples 1-10, and wherein to generate an erasure code includes to generate a plurality of erasure codes for each of a plurality of blocks of the file.

Example 12 includes the subject matter of Examples 1-11, and wherein to generate a plurality of erasure codes for each of a plurality of blocks of the file includes to generate a parity syndrome and a Galois field syndrome for each block.

Example 13 includes the subject matter of Examples 1-12, and wherein the processor is further to partition the file into one or more superblocks and a plurality of sub-blocks within each superblock.

Example 14 includes the subject matter of Examples 1-13, and wherein the processor is further to partition the file into superblocks of 8 kilobytes and sub-blocks of 64 bytes.

Example 15 includes the subject matter of Examples 1-14, and wherein the processor is further to determine an erasure code for each sub-block; determine a cyclic redundancy check (CRC) checksum for each sub-block; and determine a (CRC) checksum for each erasure code.

Example 16 includes determining, by a processor of an apparatus, an increase in file size to be allocated for a reserved portion of a file to be stored in a memory of the apparatus; generating, by the processor, an erasure code based on content of the file and the determined increase in file size, wherein the erasure code is to facilitate decorruption of the file; and writing, by the processor, the erasure code to the reserved portion of the file.

Example 17 includes the subject matter of Example 16, and further including generating, by the processor, a cyclic redundancy check (CRC) checksum based on the content of the file; and storing, by the processor, the CRC checksum in the reserved portion of the file.

Example 18 includes the subject matter of Examples 16 and 17, and wherein the reserved portion of the file is interleaved with the content of the file.

Example 19 includes the subject matter of Examples 16-18, and further including transmitting the file to a remote server compute device after storage of the erasure code in the reserved portion of the file.

Example 20 includes the subject matter of Examples 16-19, and further including reading, by the processor, the file from the memory; determining, by the processor, whether the file includes a corrupted section; and recovering, by the processor and in response to a determination that the file includes a corrupted section, the corrupted section based on the erasure code in the reserved portion of the file.

Example 21 includes the subject matter of Examples 16-20, and wherein recovering the corrupted section includes performing a matrix inversion process based on the erasure code.

Example 22 includes the subject matter of Examples 16-21, and wherein determining whether the file includes a corrupted portion comprises generating a checksum associated with the corrupted section of the file; comparing the generated checksum to a reference checksum stored in the reserved portion of the file; determining whether the generated checksum matches the reference checksum; determining, in response to a determination that the generated checksum matches the reference checksum, that the section is not corrupted; and determining, in response to a determination that the generated checksum does not match the reference checksum, that the section is corrupted.

Example 23 includes the subject matter of Examples 16-22, and further including receiving the file from a remote server compute device before the determination of whether the file includes a corrupted portion.

Example 24 includes the subject matter of Examples 16-23, and further including determining, by the processor, the increase in file size based on an attribute associated with the file.

Example 25 includes the subject matter of Examples 16-24, and wherein generating an erasure code comprises generating the erasure code based on a Reed-Solomon algorithm

Example 26 includes the subject matter of Examples 16-25, and wherein generating an erasure code comprises generating a plurality of erasure codes for each of a plurality of blocks of the file.

Example 27 includes the subject matter of Example 16-26, and wherein generating a plurality of erasure codes for each of a plurality of blocks of the file comprises generating a parity syndrome and a Galois field syndrome for each block.

Example 28 includes the subject matter of Examples 16-27, and further including partitioning, by the processor, the file into one or more superblocks and a plurality of sub-blocks within each superblock.

Example 29 includes the subject matter of Examples 16-28, and further including partitioning, by the processor, the file into superblocks of 8 kilobytes and sub-blocks of 64 bytes.

Example 30 includes the subject matter of Examples 16-29, and further including determining, by the processor, an erasure code for each sub-block; determining, by the processor, a cyclic redundancy check (CRC) checksum for each sub-block; and determining, by the processor, a (CRC) checksum for each erasure code.

Example 31 includes one or more machine-readable storage media including a plurality of instructions stored thereon that, when executed, cause an apparatus to perform the method of any of Examples 16-30.

Example 32 includes the subject matter of Example 31, and an apparatus including means for determining an increase in file size to be allocated for a reserved portion of a file to be stored in a memory of the apparatus; means for generating an erasure code based on content of the file and the determined increase in file size, wherein the erasure code is to facilitate decorruption of the file; and means for writing the erasure code to the reserved portion of the file.

Example 33 includes the subject matter of Examples 31 and 32, and further including means for generating a cyclic redundancy check (CRC) checksum based on the content of the file; and means for storing the CRC checksum in the reserved portion of the file.

Example 34 includes the subject matter of Examples 31-33, and wherein the reserved portion of the file is interleaved with the content of the file.

Example 35 includes the subject matter of Examples 31-34, and further including means for transmitting the file to a remote server compute device after storage of the erasure code in the reserved portion of the file.

Example 36 includes the subject matter of Examples 31-35, and further including means for reading the file from the memory; means for determining whether the file includes a corrupted section; and means for recovering, in response to a determination that the file includes a corrupted section, the corrupted section based on the erasure code in the reserved portion of the file.

Example 37 includes the subject matter of Examples 31-36, and wherein the means for recovering the corrupted section comprises means for performing a matrix inversion process based on the erasure code.

Example 38 includes the subject matter of Examples 31-37, and wherein the means for determining whether the file includes a corrupted portion comprises means for generating a checksum associated with the corrupted section of the file; means for comparing the generated checksum to a reference checksum stored in the reserved portion of the file; means for determining whether the generated checksum matches the reference checksum; means for determining, in response to a determination that the generated checksum matches the reference checksum, that the section is not corrupted; and means for determining, in response to a determination that the generated checksum does not match the reference checksum, that the section is corrupted.

Example 39 includes the subject matter of Examples 31-38, and further including means for receiving the file from a remote server compute device before the determination of whether the file includes a corrupted portion.

Example 40 includes the subject matter of Examples 31-39, and further including means for determining the increase in file size based on an attribute associated with the file.

Example 41 includes the subject matter of Examples 31-40, and wherein the means for generating an erasure code comprises means for generating the erasure code based on a Reed-Solomon algorithm.

Example 42 includes the subject matter of Examples 31-41, and wherein the means for generating an erasure code comprises generating a plurality of erasure codes for each of a plurality of blocks of the file.

Example 43 includes the subject matter of Examples 31-42, and wherein the means for generating a plurality of erasure codes for each of a plurality of blocks of the file comprises means for generating a parity syndrome and a Galois field syndrome for each block.

Example 44 includes the subject matter of Examples 31-43, and further including means for partitioning the file into one or more superblocks and a plurality of sub-blocks within each superblock.

Example 45 includes the subject matter of Examples 31-44, and further including means for partitioning the file into superblocks of 8 kilobytes and sub-blocks of 64 bytes.

Example 46 includes the subject matter of Examples 31-45, and further including means for determining an erasure code for each sub-block; means for determining a cyclic redundancy check (CRC) checksum for each sub-block; and means for determining a (CRC) checksum for each erasure code.

1. An apparatus comprising:
a memory to store file data; and
a processor to manage encode or decode operations on the file data, wherein the processor is to:
determine an increase in file size of a file to be stored in memory, wherein the increase in the file size of the file is to define a reserved portion of the file;
generate an erasure code based on content of the file and the determined increase in file size, wherein the erasure code is to facilitate decorruption of the file; and
write the erasure code to the reserved portion of the file.

2. The apparatus of claim 1, wherein the processor is further to:
generate a cyclic redundancy check (CRC) checksum based on the content of the file; and
store the CRC checksum in the reserved portion of the file.

3. The apparatus of claim 1, wherein the reserved portion of the file is interleaved with the content of the file.

4. The apparatus of claim 1, wherein the apparatus further comprises network communication circuitry to transmit the file to a remote server compute device after storage of the erasure code in the reserved portion of the file.

5. The apparatus of claim 1, wherein the processor is further to:
read the file from the memory;
determine whether the file includes a corrupted section; and
recover, in response to a determination that the file includes a corrupted section, the corrupted section based on the erasure code in the reserved portion of the file.

6. The apparatus of claim 5, wherein to recover the corrupted section comprises to perform a matrix inversion process based on the erasure code.

7. The apparatus of claim 5, wherein to determine whether the file includes a corrupted portion comprises to:
generate a checksum associated with the corrupted section of the file;
compare the generated checksum to a reference checksum stored in the reserved portion of the file;
determine whether the generated checksum matches the reference checksum;
determine, in response to a determination that the generated checksum matches the reference checksum, that the section is not corrupted; and
determine, in response to a determination that the generated checksum does not match the reference checksum, that the section is corrupted.

8. The apparatus of claim 5, wherein the apparatus further comprises network communication circuitry to receive the file from a remote server compute device before the determination of whether the file includes a corrupted portion.

9. The apparatus of claim 1, wherein the processor is further to determine the increase in file size based on an attribute associated with the file.

10. The apparatus of claim 1, wherein to generate an erasure code comprises to generate the erasure code based on a Reed-Solomon algorithm

11. The apparatus of claim 1, wherein to generate an erasure code comprises to generate a plurality of erasure codes for each of a plurality of blocks of the file.

12. The apparatus of claim 11, wherein to generate a plurality of erasure codes for each of a plurality of blocks of the file comprises to generate a parity syndrome and a Galois field syndrome for each block.

13. The apparatus of claim 11, wherein the processor is further to partition the file into one or more superblocks and a plurality of sub-blocks within each superblock.

14. One or more machine-readable storage media comprising a plurality of instructions stored thereon that, when executed, cause an apparatus to:
determine an increase in file size to be allocated for a reserved portion of a file to be stored in a memory of the apparatus;
generate an erasure code based on content of the file and the determined increase in file size, wherein the erasure code is to facilitate decorruption of the file; and
write the erasure code to the reserved portion of the file.

15. The one or more machine-readable storage media of claim 14, wherein the plurality of instructions, when executed, further cause the apparatus to:
generate a cyclic redundancy check (CRC) checksum based on the content of the file; and
store the CRC checksum in the reserved portion of the file.

16. The one or more machine-readable storage media of claim 14, wherein the reserved portion of the file is interleaved with the content of the file.

17. The one or more machine-readable storage media of claim 14, wherein the plurality of instructions, when executed, further cause the apparatus to transmit the file to a remote server compute device after storage of the erasure code in the reserved portion of the file.

18. The one or more machine-readable storage media of claim 14, wherein the plurality of instructions, when executed, further cause the apparatus to:
read the file from the memory;
determine whether the file includes a corrupted section; and
recover, in response to a determination that the file includes a corrupted section, the corrupted section based on the erasure code in the reserved portion of the file.

19. The one or more machine-readable storage media of claim 18, wherein to recover the corrupted section comprises to perform a matrix inversion process based on the erasure code.

20. The one or more machine-readable storage media of claim 18, wherein to determine whether the file includes a corrupted portion comprises to:
generate a checksum associated with the corrupted section of the file;
compare the generated checksum to a reference checksum stored in the reserved portion of the file;
determine whether the generated checksum matches the reference checksum;
determine, in response to a determination that the generated checksum matches the reference checksum, that the section is not corrupted; and
determine, in response to a determination that the generated checksum does not match the reference checksum, that the section is corrupted.

21. A method comprising:
determining, by a processor of an apparatus, an increase in file size to be allocated for a reserved portion of a file to be stored in a memory of the apparatus;
generating, by the processor, an erasure code based on content of the file and the determined increase in file size, wherein the erasure code is to facilitate decorruption of the file; and
writing, by the processor, the erasure code to the reserved portion of the file.

22. The method of claim 21, further comprising:
generating, by the processor, a cyclic redundancy check (CRC) checksum based on the content of the file; and
storing, by the processor, the CRC checksum in the reserved portion of the file.

23. The method of claim 21, wherein the reserved portion of the file is interleaved with the content of the file.

24. The method of claim 21, further comprising transmitting the file to a remote server compute device after storage of the erasure code in the reserved portion of the file.

25. The method of claim 21, further comprising:
reading, by the processor, the file from the memory;
determining, by the processor, whether the file includes a corrupted section; and
recovering, by the processor and in response to a determination that the file includes a corrupted section, the corrupted section based on the erasure code in the reserved portion of the file.
